(19) United States
(12) Patent Application Publication
(10) Pub. No.: US 2025/0393452 A1
(43) Pub. Date: Dec. 25, 2025

(54) DISPLAY DEVICE AND ELECTRONIC DEVICE INCLUDING THE SAME

(71) Applicant: Samsung Display Co., LTD., Yongin-si (KR)

(72) Inventors: Soo Dong KIM, Yongin-si (KR); RAE-YOUNG KIM, Yongin-si (KR); Suk Hoon KANG, Yongin-si (KR); Jung Hwan YI, Yongin-si (KR); Ho LIM, Yongin-si (KR)

(73) Assignee: Samsung Display Co., LTD., Yongin-si (KR)

(21) Appl. No.: 19/237,159

(22) Filed: Jun. 13, 2025

(30) Foreign Application Priority Data
Jun. 25, 2024 (KR) 10-2024-0083185
Oct. 16, 2024 (KR) 10-2024-0141134

(51) Int. Cl. H10K 59/80; H10K 59/122; H10K 59/38; H10K 102/00

(52) U.S. Cl. CPC H10K 59/8792; H10K 59/38; H10K 59/878; H10K 59/122; H10K 2102/331

(57) ABSTRACT

Provided is a display device including a substrate, a transistor disposed on the substrate, a light emitting element including a light emission layer disposed on the transistor, and electrically connected to the transistor, a bank disposed on the light emitting element, and including an opening, a color conversion layer disposed in the opening, and including a quantum dot, a reflection layer disposed on an upper surface and side surface of the bank, and an anti-reflection layer covering at least a portion of an upper surface and a side surface of the reflection layer.

### CROSS-REFERENCE TO RELATED APPLICATION(S)

This application claims priority to and the benefit of Korean Patent Application No. 10-2024-0141134 under 35 U.S.C. § 119, filed on Oct. 16, 2024, and Korean Patent Application No. 10-2024-0083185 under 35 U.S.C. § 119, filed on Jun. 25, 2024, in the Korean Intellectual Property Office, the entire contents of which are incorporated herein by reference.

### BACKGROUND

### 1. Technical Field

The disclosure generally relates to a display device.

### 2. Description of the Related Art

A light emitting element is a device that forms an exciton by combining a hole supplied by an anode and an electron supplied by a cathode in a light emission layer formed between the anode and the cathode, and emits light as excitons are stabilized.

The light emitting element has various merits such as a wide viewing angle, fast response speed, thin thickness, and low power consumption, and thus it is widely applied to various electrical and electronic devices such as televisions, monitors, and mobile phones.

Recently, in order to implement a high-efficiency display device, a display device including a color conversion layer has been proposed. The color conversion layer may convert color of incident light into another color.

### SUMMARY

The disclosure attempts to provide a display device capable of improving visibility by decreasing external light reflection.

The display device may include a substrate, a transistor disposed on the substrate, a light emitting element including a light emission layer disposed on the transistor, and electrically connected to the transistor, a bank disposed on the light emitting element, and including an opening, a color conversion layer disposed in the opening, and including a quantum dot, a reflection layer disposed on an upper surface and side surface of the bank, and an anti-reflection layer covering at least a portion of an upper surface and a side surface of the reflection layer.

The reflection layer may include a first area covering the side surface of the bank, and a second area covering the upper surface of the bank and an edge portion of the color conversion layer on the first area.

The display device may further include an insulation pattern disposed on the color conversion layer, where the second area covers at least a portion of the upper surface of the insulation pattern.

The insulation pattern may have a refractive index value different from a refractive index of the color conversion layer.

The insulation pattern may include a plurality of layers having refractive indices different from each other.

The display device may further include a filling layer disposed on the anti-reflection layer and the insulation pattern, where an upper surface of the anti-reflection layer is in contact with the filling layer, and a lower surface of the anti-reflection layer is in contact with the reflection layer.

A void area may be disposed between the filling layer and the insulation pattern.

The void area may be in a vacuum state.

The void area may include air or an inert gas.

The display device may further include a moisture absorbing layer disposed on the insulation pattern, where the void area is disposed between the moisture absorbing layer and the filling layer.

The display device may further include color filter layers disposed on the color conversion layer, where the anti-reflection layer and at least one of the color filter layers may include a same material.

The color filter layers may include a first color filter layer that transmits red light, a second color filter layer that transmits green light, and a third color filter layer that transmits blue light, and the anti-reflection layer and the third color filter layer may include a same material.

The anti-reflection layer may further include a first anti-reflection layer and a second anti-reflection layer disposed on the first anti-reflection layer disposed on the reflection layer, and the first anti-reflection layer and the second anti-reflection layer may include different materials.

The display device may further include a pixel defining layer disposed on sides of the light emission layer, where a width of the anti-reflection layer in a horizontal direction is greater than or equal to a width of the bank in the horizontal direction, and is smaller than or equal to a width of the pixel defining layer in the horizontal direction.

The reflection layer may include a metallic material.

The display device may include a substrate, a transistor disposed on the substrate, a light emitting element including a light emission layer disposed on the transistor, and electrically connected to the transistor, a bank disposed on the light emitting element, and including an opening, a color conversion layer disposed in the opening of the bank, and including a quantum dot, and a reflection layer disposed on a side surface of the bank, where the reflection layer may include a first area covering the side surface of the bank, and the second area covering an edge portion of the color conversion layer on the first area.

The display device may further include an anti-reflection layer covering at least a portion of an upper surface and a side surface of the reflection layer.

The display device may further include an insulation pattern disposed on the color conversion layer, where the second area covers at least a portion of the pattern upper surface.

The insulation pattern may have a refractive index value different from a refractive index of the color conversion layer.

The display device may further include a pixel defining layer disposed on sides of the light emission layer, a width of an anti-reflection layer in a horizontal direction is greater than or equal to a width of the bank in the horizontal direction, and smaller than or equal to a width of the pixel defining layer in the horizontal direction.

The display device according to an embodiment may be disposed below a color filter, and may include an anti-reflection layer that partially overlaps the color conversion layer in the thickness direction (or third direction DR3). The reflection of light incident from the outside of the display device may be decreased so that visibility of the display device may be improved.

The display device according to an embodiment may include a reflection layer disposed between the color conversion layer and the bank. According to an embodiment, a time for which the light emitted from the light emission layer stays in the color conversion layer may be increased, and accordingly, light conversion efficiency of the display device may be increased.

The electronic device, according to an embodiment includes a display device which includes a substrate, a transistor disposed on the substrate, a light emitting element including a light emission layer disposed on the transistor, and electrically connected to the transistor, a bank disposed on the light emitting element, and including an opening, a color conversion layer disposed in the opening of the bank, and including a quantum dot, a reflection layer disposed on an upper surface and a side surface of the bank, and an anti-reflection layer covering at least a portion of an upper surface and a side surface of the reflection layer.

The reflection layer includes a first area covering a side surface of the bank and a second area covering the upper surface of the bank and an edge portion of the color conversion layer on the first area.

The electronic device further includes an insulation pattern disposed on the color conversion layer, wherein the second area covers at least a portion of the upper surface of the insulation pattern.

The electronic device, according to an embodiment includes a display device which includes a substrate, a transistor disposed on the substrate, a light emitting element including a light emission layer disposed on the transistor, and electrically connected to the transistor, a bank disposed on the light emitting element, and including an opening, a color conversion layer disposed in the opening of the bank, and including a quantum dot, and a reflection layer disposed on a side surface of the bank, wherein the reflection layer includes a first area covering the side surface of the bank, and a second area covering an edge portion of the color conversion layer on the first area.

The electronic device further includes an anti-reflection layer covering at least a portion of an upper surface and a side surface of the reflection layer.

### BRIEF DESCRIPTION OF THE DRAWINGS

FIG. 1 is an exploded schematic perspective view of a display device according to an embodiment.

FIG. 2 is a schematic cross-sectional view of a display panel according to an embodiment.

FIG. 3 is a schematic plan view of a display panel according to an embodiment.

FIG. 4 is a schematic plan view of a display panel according to an embodiment.

FIG. 5 is a schematic cross-sectional view of a display panel according to an embodiment.

FIG. 6A and FIG. 6B are enlarged schematic cross-sectional views representing the “A” area of FIG. 5.

FIG. 7 and FIG. 8 are drawings for schematically explaining a shape of an anti-reflection layer according to an embodiment in detail.

FIG. 9 is a schematic cross-sectional view of a display panel according to an embodiment.

FIG. 10 is a schematic cross-sectional view of a display panel according to an embodiment.

FIG. 11 is a schematic cross-sectional view of a display panel according to an embodiment.

FIG. 12 is a schematic cross-sectional view of a display panel according to an embodiment.

FIG. 13 is a schematic cross-sectional view of a display panel according to an embodiment.

FIG. 14 is a schematic plan view of a display panel according to an embodiment.

FIG. 15 is a schematic plan view of a display panel according to an embodiment.

FIG. 16 to FIG. 22 are schematic process cross-sectional views for explaining a manufacturing method of a display panel according to an embodiment.

FIG. 23 is a schematic block diagram of an electronic device according to an embodiment.

FIG. 24 shows schematic diagrams of electronic devices according to various embodiments.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean within one or more standard deviations, or within ±20%, ±10%, or ±5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

The disclosure will be described more fully hereinafter with reference to the accompanying drawings, in which embodiments of the disclosure are shown. As those skilled in the art would realize, the described embodiments may be modified in various different ways, all without departing from the spirit or scope of the disclosure.

To clearly describe the disclosure, parts that are irrelevant to the description are omitted, and like elements are designated by like reference numerals throughout the disclosure.

To clearly describe the disclosure, parts that are irrelevant to the description are omitted, and like reference numerals designate like elements throughout the disclosure. The thicknesses of layers, films, panels, areas, etc., are enlarged for clarity. The thicknesses of some layers and areas are exaggerated.

It should be understood that when an element such as a layer, film, area, or substrate is referred to as being “on” another element, it can be directly on the other element or intervening elements may also be present. In contrast, when an element is referred to as being “directly on” another element, there are no intervening elements present. The word “on” or “above” means disposed on or below the object portion, and does not necessarily mean disposed on the upper side of the object portion based on a gravitational direction.

The phrase “in a plan view” means viewing a target portion from the top, and the phrase “in a cross-sectional view” means viewing a cross-section formed by perpendicularly cutting a target portion from the side.

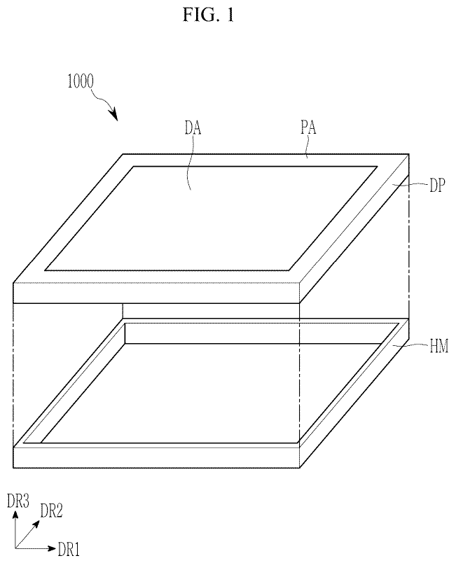

Hereinafter, a display device according to an embodiment will be described with reference to FIG. 1. FIG. 1 is an exploded schematic perspective view of a display device according to an embodiment.

Referring to FIG. 1, a display device 1000 according to an embodiment may include a display panel DP and a housing HM.

In the display panel DP, one surface on which an image is displayed may be parallel to a plane defined by a first direction DR1 and a second direction DR2. A normal direction of one surface on which the image is displayed, for example, a thickness direction of the display panel DP, may be indicated by a third direction DR3 (e.g., thickness direction). A front surface (or upper surface) and a back surface (or lower surface) of each member may be distinguished by the third direction DR3. However, directions indicated by the first to third directions DR1, DR2, and DR3 may be merely relative concepts and may be converted to different directions.

The display panel DP may be a flat rigid display panel, but is not limited thereto and may be a flexible display panel. Meanwhile, the display panel DP may be an organic light emitting display panel. However, a type of the display panel DP is not limited thereto, and may be various types of panels. For example, the display panel DP may be a liquid crystal display panel, an electrophoretic display panel, an electrowetting display panel, or the like. The display panel DP may be a next-generation display panel such as a micro-light emitting diode display panel, a quantum dot light emitting diode display panel, a quantum dot organic light emitting diode display panel, or the like.

The micro-light emitting diode (micro-LED) display panel may be made up of light emitting diodes ranging in size from 10 to 100 micrometers, with each pixel comprising a light emitting diode. These micro-light emitting diode display panels may have advantages of using inorganic materials, omitting a backlight, having fast reaction speed, realizing high luminance with low electric power, and not being broken when bending.

The quantum dot light emitting diode display panel may be made by attaching a film including quantum dots or by being formed of a material including quantum dots. The quantum dots are made of inorganic materials such as indium, cadmium, etc., which emit light by themselves, and may mean particles with a diameter of several nanometers or less. The quantum dot LED display panel may display light of a desired color by adjusting the particle size of the quantum dots. The quantum dot-organic light emitting diode (QD-OLED) display panel is made by a method using a blue organic light emitting diode as a light source, and attaching a film including red and green quantum dots thereon or depositing a material including red and green quantum dots to implement a color. The display panel DP according to an embodiment may be a variety of other display panels.

As shown in FIG. 1, the display panel DP may include a display area DA on which an image is displayed, and a peripheral area PA adjacent to the display area DA. The peripheral area PA may be an area where the image is not displayed. In a plan view, the display area DA may have, for example, a rectangular shape, and the peripheral area PA may have a shape surrounding the display area DA. However, the disclosure is not limited thereto, and the shapes of the display area DA and the peripheral area PA may be relatively designed.

The housing HM may provide a predetermined interior space. The display panel DP may be mounted inside the housing HM. In addition to the display panel DP, various electronic parts, for example, a power supply unit, a storage device, an audio input/output module, etc., may be mounted inside the housing HM.

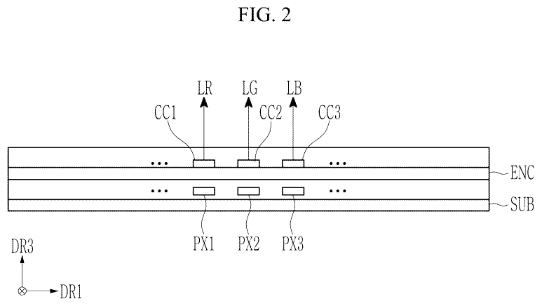

Hereinafter, a display area of a display panel according to an embodiment will be described with reference to FIG. 2. FIG. 2 is a schematic cross-sectional view of a display panel according to an embodiment.

Referring to FIG. 2, multiple pixels PX1, PX2, and PX3 may be formed on a substrate SUB corresponding to the display area DA of FIG. 1. Each of the first to third pixels PX1, PX2, and PX3 may include multiple transistors and a light emitting element connected thereto. In this disclosure, the shape and arrangement of multiple pixels PX1, PX2, and PX3 may be modified in various ways.

An encapsulation layer ENC may be disposed on multiple pixels PX1, PX2, and PX3. The display area DA may be protected from external air, moisture, or the like through the encapsulation layer ENC. The encapsulation layer ENC may be integrally provided to overlap the entire area of the display area DA (see FIG. 1), and may be partially disposed on a peripheral area (or non-display area) PA (see FIG. 1).

A first color converter CC1, a second color converter CC2, and a transmitting portion CC3 may be disposed on the encapsulation layer ENC. The first color converter CC1 may overlap a first pixel PX1, the second color converter CC2 may overlap a second pixel PX2, and the transmitting portion CC3 may overlap a third pixel PX3.

Light emitted from the first pixel PX1 may pass through the first color converter CC1, to provide a red light LR. Light emitted from the second pixel PX2 may pass through the second color converter CC2, to provide a green light LG. Light emitted from the third pixel PX3 may pass through the transmitting portion CC3, to provide a blue light LB.

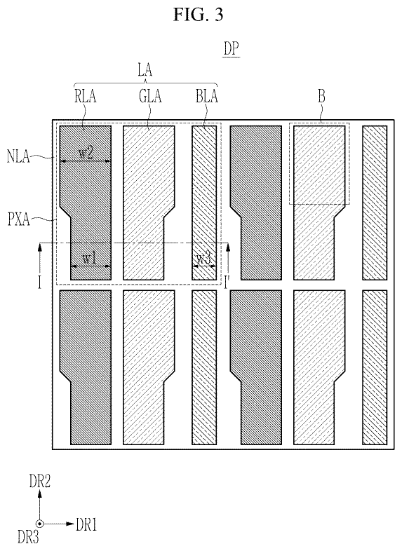

FIG. 3 is a schematic plan view of a display panel according to an embodiment.

Referring to FIG. 3, the display panel DP according to an embodiment may include unit pixel areas PXA arranged in the first direction DR1 and the second direction DR2. In FIG. 3, four unit pixel areas PXA are shown arranged in the first direction DR1 and the second direction DR2, but the number of the unit pixel areas PXA included in the display panel DP is not limited. In another embodiment, the number of unit pixel areas PXA may be more than 4 or less than 4 in the first direction DR1 and the second direction DR2.

The unit pixel areas PXA may include a light emitting area LA and a non-light emitting area NLA, respectively. The light emitting area LA may be an area where the light emitted from each of the pixels PX1, PX2, and PX3 described with reference to FIG. 2 is emitted to the outside. The light emitting area LA may include a red-light emitting area RLA, a green-light emitting area GLA, and a blue-light emitting area BLA. The red light LR may be emitted from the red-light emitting area RLA, the green light LG may be emitted from the green-light emitting area GLA, and the blue light LB may be emitted from the blue-light emitting area BLA, respectively.

The non-light emitting area NLA may be an area where light is blocked. In a plan view, the non-light emitting area NLA may have a form surrounding edges of the light emitting area LA. For example, each of the red-light emitting area RLA, the green-light emitting area GLA, and the blue-light emitting area BLA may be surrounded by the non-light emitting area NLA. In the non-light emitting area NLA, the light emitted from each of the pixels PX1, PX2, and PX3 described with reference to FIG. 2 may not be emitted to the outside but blocked. In the non-light emitting area NLA, light incident on a front surface of the display device from the outside of the display device may be absorbed.

The unit pixel area PXA may include one red-light emitting area RLA, one green-light emitting area GLA, and one blue-light emitting area BLA. The red-light emitting area RLA, the green-light emitting area GLA, and the blue-light emitting area BLA may be arranged to be spaced apart in the first direction DR1, in the unit pixel area PXA. The light emitting areas RLA, GLA, and BLA may each extend in the second direction DR2. At least one of the red-light emitting area RLA, the green-light emitting area GLA, and the blue-light emitting area BLA may have an area different from other light emitting areas RLA, GLA, and BLA. For example, among the light emitting areas RLA, GLA, and BLA included in one unit pixel area PXA, the blue-light emitting area BLA may have an area different from the red-light emitting area RLA and the green-light emitting area GLA. The red-light emitting area RLA and the green-light emitting area GLA may have substantially the same shape and area.

A width of the red-light emitting area RLA in the first direction DR1 may not be constant. For example, referring to FIG. 3, the width of the red-light emitting area RLA in the first direction DR1 may extend in the second direction DR2 while having a first width w1, and then may gradually increase from a certain point. The width of the red-light emitting area RLA in the first direction DR1 may increase to a second width w2 that is greater than the first width w1, and then may extend in the second direction DR2 while maintaining the second width w2. The red-light emitting area RLA may have a substantially “L” shape with the top and bottom and side-to-side inverted.

A width of the green-light emitting area GLA in the first direction DR1 may not be constant. For example, referring to FIG. 3, the width of the green-light emitting area GLA in the first direction DR1 may extend in the second direction DR2 while having the first width w1, and then may gradually increase from a certain point. The width of the green-light emitting area GLA in the first direction DR1 may increase to the second width w2 that is wider than the first width w1, and then may extend in the second direction DR2 while maintaining the second width w2. The green light emitting area GLA may be substantially shaped like an inverted “L.”

The green-light emitting area GLA may have a shape with the red-light emitting area RLA inverted from side to side.

A width of the blue-light emitting area BLA in the first direction DR1 may be constant. The blue-light emitting area BLA may have a rectangular shape. For example, referring to FIG. 3, the width of the blue-light emitting area BLA in the first direction DR1 may extend in the second direction DR2 while having third width w3. The third width w3 may be narrower than the first width w1 and the second width w2. However, it is not limited thereto, and the third width w3 may be wider that least one of the first width w1 and the second width w2.

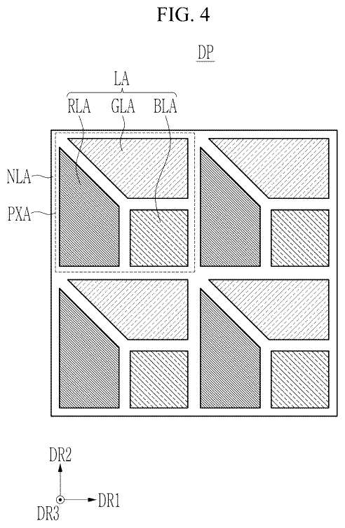

FIG. 4 is a schematic plan view of a display panel according to an embodiment. FIG. 4 is a schematic plan view of a display panel DP having a planar shape different from the planar shape of the display panel DP described with reference to FIG. 3. Hereinafter, differences from the display panel DP described with reference to FIG. 3 will be mainly described.

Referring to FIG. 4, the display panel DP according to an embodiment may have a generally square shape in a plan view.

The display panel DP according to an embodiment may include the unit pixel areas PXA arranged in the first direction DR1 and the second direction DR2. The unit pixel area PXA may include a light emitting area LA and a non-light emitting area NLA, respectively. Each of the light emitting area LA may include one red-light emitting area RLA, one green-light emitting area GLA, and one blue-light emitting area BLA.

The red-light emitting area RLA and the green-light emitting area GLA may each have a trapezoid shape including one inclined side. Referring to FIG. 4, the red-light emitting area RLA and the green-light emitting area GLA may be disposed so that respective inclined sides may face each other, in the unit pixel area PXA. For example, a short side among two parallel opposite sides of the red-light emitting area RLA may be perpendicular to a short side among two parallel opposite sides of the green-light emitting area GLA. A long side among the two parallel opposite sides of the red-light emitting area RLA may be perpendicular to a long side among the two parallel opposite sides of the green-light emitting area GLA. The red-light emitting area RLA and the green-light emitting area GLA may have substantially the same area.

The blue-light emitting area BLA may have a square shape. However, although it is not limited thereto, the blue-light emitting area BLA may have a rectangular shape. The blue-light emitting area BLA may be disposed so that one side thereof may face the short side among the two parallel opposite sides of the red-light emitting area RLA. For example, another side perpendicular to the one side of the blue-light emitting area BLA may face the short side among the two parallel opposite sides of the green-light emitting area GLA. An area of the blue-light emitting area BLA may be smaller than areas of the red-light emitting area RLA and the green-light emitting area GLA.

The non-light emitting area NLA may be disposed between the red-light emitting area RLA, the green-light emitting area GLA, and the blue-light emitting area BLA.

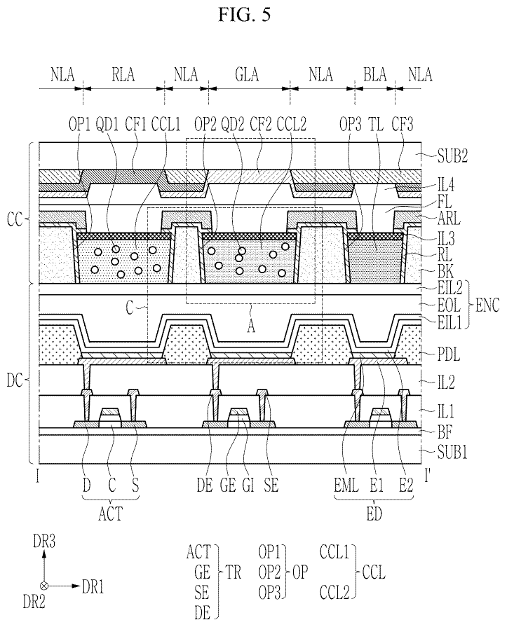

FIG. 5 is a schematic cross-sectional view of a display panel according to an embodiment. For example, FIG. 5 is a schematic cross-sectional view of the display panel DP taken along line I-I′ of FIG. 3.

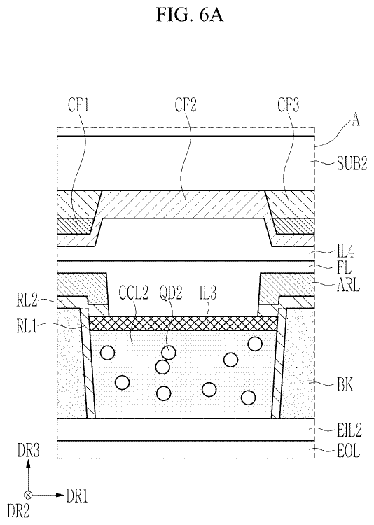

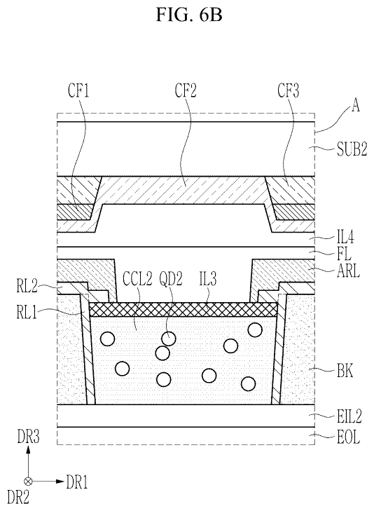

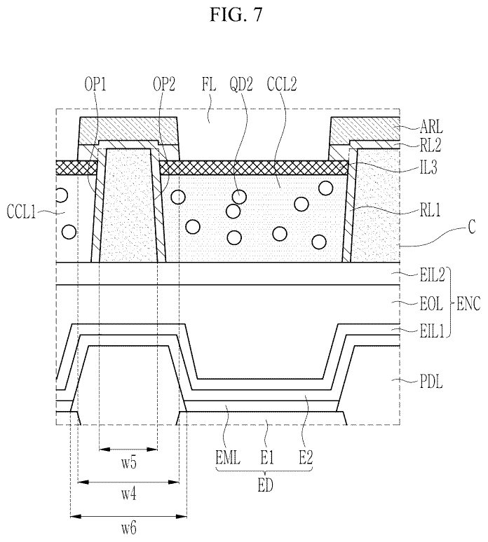

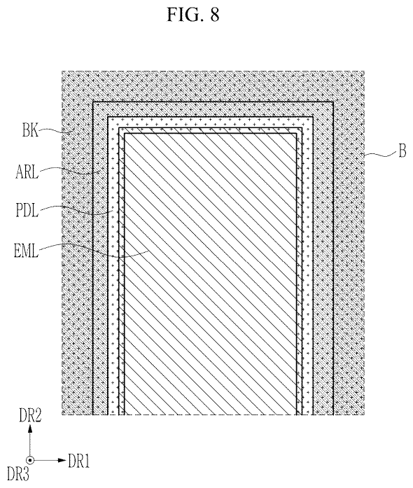

Hereinafter, the structure of the display panel DP according to an embodiment will be described in more detail, with reference to FIG. 5 to FIG. 8. FIG. 5 is a schematic cross-sectional view of a display panel according to an embodiment, FIG. 6A and FIG. 6B are enlarged schematic cross-sectional views representing the “A” area of FIG. 5, and FIG. 7 and FIG. 8 are drawings for schematically explaining a shape of an anti-reflection layer according to an embodiment in detail. FIG. 7 is enlarged schematic cross-sectional views representing the “C” area of FIG. 5. FIG. 8 is an enlarged schematic plan view representing the “B” area of FIG. 3.

Firstly, referring to FIG. 5, the display area DA according to an embodiment may include the red-light emitting area RLA, the green-light emitting area GLA, and the blue-light emitting area BLA. The non-light emitting area NLA may be disposed between the red-light emitting area RLA, the green-light emitting area GLA, and the blue-light emitting area BLA. Each light emitting area may correspond to a pixel. For example, the blue-light emitting area BLA, the red-light emitting area RLA and the green-light emitting area GLA may correspond to a blue pixel, a red pixel, and a green pixel, respectively.

Hereinafter, the cross-sectional structure will be described.

The display panel may include a display unit DC, and the color converter CC disposed on the display unit DC. The display unit DC may include a first substrate SUB1, a transistor TR disposed on the first substrate SUB1, and including a gate electrode GE, a semiconductor layer ACT, a source electrode SE and a drain electrode DE, and a light emitting element ED disposed on the transistor TR. The color converter CC may include a bank BK disposed on the light emitting element ED and including an opening OP, a color conversion layer CCL disposed in the opening OP, a reflection layer RL disposed on the bank BK, and an anti-reflection layer ARL disposed on the reflection layer RL.

The first substrate SUB1 may include a flexible material such as plastic that can be curved, bent, folded, or rolled. A buffer layer BF may be further disposed on the first substrate SUB1. In another embodiment, the buffer layer BF may be omitted. The buffer layer BF may include an insulating material. For example, the buffer layer BF may include at least one of silicon nitride (SiNₓ), silicon oxide (SiOₓ), and silicon oxynitride (SiOₓN_{y}). The buffer layer BF may be disposed between the first substrate SUB1 and the semiconductor layer ACT, block impurities from the first substrate SUB1 during a crystallization process for forming polycrystalline silicon to improve characteristics of polycrystalline silicon, and planarize the first substrate SUB1 to alleviate the stress on the semiconductor layer ACT formed on the buffer layer BF.

The transistors TR may be disposed on the buffer layer BF. The transistors TR may each include the gate electrode GE, the semiconductor layer ACT, the source electrode SE and the drain electrode DE. The semiconductor layer ACT may be disposed on the buffer layer BF. The semiconductor layer ACT may be formed of polycrystalline silicon or oxide semiconductor. The semiconductor layer ACT may include a channel area C, a source area S, and a drain area D. The source area S and the drain area D may be disposed on either side of the channel area C. The channel area C may be an intrinsic semiconductor that is not doped with impurities, and the source area S and the drain area D may be impurity semiconductors doped with conductive impurities. The semiconductor layer ACT may be formed of an oxide semiconductor, and for example, a separate protective layer (not shown) may be added to protect the oxide semiconductor material that is vulnerable to an external environment such as high temperature.

A gate insulation layer GI may be disposed on the semiconductor layer ACT. The gate insulation layer GI may include an insulating material. For example, the gate insulation layer GI may be a single layer or multiple layers including at least one of silicon nitride (SiNₓ), silicon oxide (SiOₓ), and silicon oxynitride (SiOₓN_{y}).

The gate electrode GE may be disposed on the gate insulation layer GI, and the gate electrode GE may be a multilayer in which a metal layer containing any one of copper (Cu), a copper alloy, aluminum (Al), an aluminum alloy, molybdenum (Mo), and a molybdenum alloy is stacked.

A first interlayer insulating layer IL1 may be further disposed on the gate electrode GE and the gate insulation layer GI. The first interlayer insulating layer IL1 may include an insulating material. For example, the first interlayer insulating layer IL1 may include at least one of silicon nitride (SiNₓ), silicon oxide (SiOₓ), and silicon oxynitride (SiOₓN_{y}). Each of the openings exposing the source area S and the drain area D may be disposed in the first interlayer insulating layer IL1.

The source electrode SE and the drain electrode DE may be disposed on the first interlayer insulating layer IL1. The source electrode SE and the drain electrode DE may be electrically connected to the source area S and the drain area D of the semiconductor layer ACT, respectively, through the opening formed in the first interlayer insulating layer IL1.

A protective layer IL2 may be further disposed on the first interlayer insulating layer IL1, the source electrode SE, and the drain electrode DE. Since the protective layer IL2 may cover and planarize the first interlayer insulating layer IL1, the source electrode SE, and the drain electrode DE, a first electrode E1 may be formed on the protective layer IL2 without a step. The protective layer IL2 may be made of an organic material such as polyacrylate resin or polyimide resin, or a laminated film of organic and inorganic materials.

The light emitting element ED may be disposed on the protective layer IL2. The light emitting element ED may include the first electrode E1, a light emission layer EML disposed on the first electrode E1, and a second electrode E2 disposed on the light emission layer EML.

The light emitting element ED may be electrically connected to the drain electrode DE of the transistor TR, through the opening formed in the protective layer IL2. The transistor TR may be a driving transistor. For example, the transistor TR may be electrically connected to the first electrode E1 included in the light emitting element ED to supply a driving current to the light emitting element ED. In addition to the driving transistor, a display device according to an embodiment may further include a switching transistor (not shown) electrically connected to a data line and to transfer a data voltage in response to a scan signal and a compensation transistor (not shown) or the like electrically connected to the driving transistor and to compensate a threshold voltage of the driving transistor in response to the scan signal.

The display panel DP according to an embodiment may further include a pixel defining layer PDL disposed on both sides of the first electrode E1. The pixel defining layer PDL may also be disposed on the protective layer IL2 and the first electrode E1. The pixel defining layer PDL may have a pixel opening that overlaps the first electrode E1 and defines the light emitting area. The pixel defining layer PDL may include an organic material such as polyacrylate resin, polyimide resin, or a silica-based inorganic material. The pixel opening may have a planar shape substantially similar to the first electrode E1, and in a plan view, may have a rhombus or an octagonal shape similar to a rhombus, but is not limited thereto, and may have any shape such as a rectangle or a polygon.

The light emission layer EML may be disposed on the first electrode E1 overlapping the pixel opening. The light emission layer EML may be formed of a low-molecular organic material or a polymer organic material such as poly(3,4-ethylenedioxythiophene) (PEDOT). The light emission layer EML may be a multilayer further including at least one of a hole injection layer, a hole transport layer, an electron transport layer, and an electron injection layer. Most of the light emission layer EML may be disposed in the pixel opening, and may also be disposed on a side surface or above the pixel defining layer PDL.

The second electrode E2 may be disposed on the light emission layer EML. The second electrode E2 may be disposed over multiple pixels and may be applied with a common voltage through a common voltage transfer unit (not shown) of the peripheral area (or non-display area).

The first electrode E1 may be an anode, which is a hole injection electrode, and the second electrode E2 may be a cathode, which is an electron injection electrode. However, the embodiment is not limited thereto, and depending on the driving method of the display device, the first electrode E1 may be a cathode, and the second electrode E2 may be an anode.

Holes and electrons may be injected into the light emission layer EML from the first electrode E1 and the second electrode E2, and light emission may occur in case that the excitons formed by the injected holes and electrons fall from the exited state to the ground state.

The light emitting element ED according to an embodiment may include multiple light emitting units. Each light emitting unit may include the light emission layer. The light emitting element ED may be a light emitting element with a tandem structure. Multiple light emitting layers may emit the same light or different light. As an example, the light emitting element ED may emit light in which green light and blue light are mixed, or it may emit blue light.

A display panel according to an embodiment may further include the encapsulation layer ENC disposed on the second electrode E2. The encapsulation layer ENC may seal the display layer by covering not only an upper surface but also a side surface of a display layer including the light emitting element ED.

Because the light emitting element ED is vulnerable to moisture and oxygen, the encapsulation layer ENC may seal the display layer to block inflow of external moisture and oxygen. The encapsulation layer ENC may include multiple layers, and may be formed as a composite layer including both an organic layer and an inorganic layer, and may be formed as a triple layer in which a first inorganic layer EIL1, an organic layer EOL, and a second inorganic layer EIL2 are sequentially formed. However, it is not limited thereto, and the number and material of the layers configuring the encapsulation layer ENC may be modified in various ways.

The bank BK may be disposed on the encapsulation layer ENC. The bank BK may include a first opening OP1, a second opening OP2, and a third opening OP3 overlapping the pixel opening. The first opening OP1, the second opening OP2, and the third opening OP3 may have different or identical sizes. A width of the bank BK in a horizontal direction (or first direction DR1) may gradually decrease away from the encapsulation layer ENC in the thickness direction (or third direction DR3).

A first color conversion layer CCL1, a second color conversion layer CCL2, and a transmission layer TL may be disposed inside the first opening OP1, the second opening OP2, and the third opening OP3, respectively.

The first color conversion layer CCL1 may convert supplied light into red light. The first color conversion layer CCL1 may include a base material and first quantum dots QD1 included in the base material. The second color conversion layer CCL2 may be disposed in the second opening OP2. The second color conversion layer CCL2 may convert supplied light into green light. The second color conversion layer CCL2 may include a base material and second quantum dot QD2 included in the base material. Base materials included in the first color conversion layer CCL1 and the second color conversion layer CCL2 may be selected from materials having high light transmittance and excellent dispersion characteristics for quantum dots. For example, base material may include an organic material such as an epoxy-based resin, an acryl-based resin, a cardo-based resin, or an imide-based resin.

The quantum dots (hereinafter, also referred to as semiconductor nanocrystals) may include a Group II-VI compound, a Group III-V compound, a Group IV-VI compound, a Group IV element or compound, a Group I-III-VI compound, a Group II-III-VI compound, a Group I-II-IV-VI compound, or a combination thereof.

The Group II-VI compounds may include a binary compound selected from the group consisting of CdSe, CdTe, ZnS, ZnSe, ZnTe, ZnO, HgS, HgSe, HgTe, MgSe, MgS and mixtures thereof; a ternary compound selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof. The Group II-VI compound may further include a Group III metal.

The Group III-V compound may include a binary compound selected from the group consisting of GaN, GaP, GaAs, GaSb, AlN, AlP, AlAs, AlSb, InN, InP, InAs, InSb and mixtures thereof; a ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and mixtures thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAINAs, InAINSb, InAlPAs, InAlPSb, InZnP, and mixtures thereof. The Group III-V compound may further include a Group II metal (e.g., InZnP).

The Group IV-VI compound may include a binary compound selected from the group consisting of SnS, SnSe, SnTe, PbS, PbSe, PbTe and mixtures thereof; a ternary compound selected from the group consisting of SnSeS, SnSeTe, SnSTe, PbSeS, PbSeTe, PbSTe, SnPbS, SnPbSe, SnPbTe and mixtures thereof; and a quaternary compound selected from the group consisting of SnPbSSe, SnPbSeTe, SnPbSTe and mixtures thereof.

The Group IV element or compound may include a mono-elemental compound selected from the group consisting of Si, Ge, and combinations thereof; and a binary compound selected from the group consisting of SiC, SiGe, and combinations thereof, but it is not limited thereto.

Examples of the Group I-III-VI compound may include CuInSe2, CuInS2, CuInGaSe, and CuInGaS, but it is not limited thereto. Examples of the Group I-II-IV-VI compound may include CuZnSnSe, and CuZnSnS, but it is not limited thereto. The Group IV element or compound may be selected from the group consisting of: a mono-elemental compound selected from the group consisting of Si, Ge, and a mixture thereof; and a binary compound selected from the group consisting of SiC, SiGe, and a mixture thereof.

The Group II-III-VI compound may be selected from the group consisting of: ZnGaS, ZnAlS, ZnlnS, ZnGaSe, ZnAlSe, ZnlnSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and combination thereof, but it is not limited thereto.

The Group I-II-IV-VI compound may be selected from CuZnSnSe and CuZnSnS, but it is not limited thereto.

The quantum dots may not include cadmium. The quantum dots may include a semiconductor nanocrystal based on Group III-V compounds including indium and phosphorus. The Group III-V compound may further include zinc. The quantum dots may include a semiconductor nanocrystal based on the Group II-VI compound including a chalcogen element (e.g., sulfur, selenium, tellurium, or combinations thereof) and zinc.

In the quantum dots, the binary compound, the ternary compound, and/or the quaternary compound described above may exist in the particles with uniform concentration, or may exist in the same particle by being divided into different states with partially different concentration distribution. They may have a core/shell structure in which one quantum dot surrounds another quantum dot. An interface between the core and the shell may have a concentration gradient in which a concentration of an element existing in the shell is gradually reduced toward the center thereof.

In some embodiments, the quantum dots may have a core-shell structure including a core including the nanocrystals described above and a shell surrounding the core. The shell of the quantum dots may function as a protective layer for maintaining the semiconductor characteristics by preventing chemical denaturation of the core and/or as a charging layer for providing electrophoretic characteristics to the quantum dots. The shell may be a single layer or a multilayer. An interface between the core and the shell may have a concentration gradient in which a concentration of an element existing in the shell is gradually reduced toward the center thereof. Examples of the shell of the quantum dots may include a metallic or non-metallic oxide, a semiconductor compound, a combination thereof, or the like.

Examples of the metallic or non-metallic oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or a ternary compound such as MgAl₂O₄, CoFe₂O₄, NiFe₂O₄, CoMn₂O₄, but the disclosure is not limited thereto.

Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like, but the disclosure is not limited thereto.

An interface between the core and the shell may have a concentration gradient in which a concentration of an element existing in the shell is gradually reduced toward the center thereof. The semiconductor nanocrystal may have a structure including one semiconductor nanocrystal core and a multi-layered shell surrounding the semiconductor nanocrystal core. The multi-layered shell may have two or more layers, for example, two, three, four, five, or more layers. Two adjacent layers of the shell may have a single composition or different compositions. Each layer in the multi-layered shell may have a composition that varies along the radius.

The quantum dots may have a full width at half maximum (FWHM) of an emission wavelength spectrum of about 45 nm or less, preferably about 40 nm or less, more preferably about 30 nm or less, and the color purity or color reproducibility may be improved in this range. Light emitted through the quantum dots may be output in all directions, thereby providing a wider viewing angle.

Regarding the quantum dots, a shell material and a core material may have different energy bandgaps. For example, the energy bandgap of the shell material may be greater than that of the core material. For another example, the energy bandgap of the shell material may be smaller than that of the core material. The quantum dots may have a multi-layered shell. The energy bandgap of an outer layer in the multi-layered shell may be greater than the energy bandgap of an inner layer (i.e., a layer that is closer to the core). The energy bandgap of the outer layer in the multi-layered shell may be less than the energy bandgap of the inner layer.

The quantum dots may adjust absorption/emission wavelength by adjusting the composition and the size thereof. The maximum emission peak wavelength of the quantum dots may have a wavelength range from ultraviolet to infrared or higher.

The quantum dots may have a quantum efficiency of about 10% or more, for example, about 30% or more, about 50% or more, about 60% or more, about 70% or more, about 90% or more, or even about 100%. The quantum dots may have a relatively narrow spectrum. The quantum dots may have a full width at half maximum of the emission wavelength spectrum, for example, about 50 nm or less, about 45 nm or less, about 40 nm or less, or about 30 nm or less.

The quantum dots may have a particle size of about 1 nm or more and about 100 nm or less. The particle size may mean a diameter of the particle or a diameter converted from a two-dimensional image obtained by transmission electron microscopy analysis, assuming a spherical shape. The quantum dots may have a size of about 1 nm to about 20 nm, for example, about 2 nm or more, about 3 nm or more, or about 4 nm or more and about 50 nm or less, about 40 nm or less, about 30 nm or less, about 20 nm or less, about 15 nm or less, and about 10 nm or less. The shape of the quantum dots may not be specifically limited. For example, the shape of the quantum dots may include a sphere, a polyhedron, a pyramid, a multi-pod, a square, a rectangular parallelepiped, a nanotube, a nanorod, a nanowire, a nanosheet, or a combination thereof, but it is not limited thereto.

The quantum dots may be commercially available or may be appropriately synthesized. The particle size of the quantum dots may be relatively freely adjusted and controlled to be uniform after colloid-synthesized.

The quantum dots may include an organic ligand (e.g., having a hydrophobic moiety and/or hydrophilic moiety). The organic ligand moiety may be coupled to a surface of the quantum dots. The organic ligands may include RCOOH, RNH2, R2NH, R3N, RSH, R3PO, R3P, ROH, RCOOR, RPO(OH)2, RHPOOH, R2POOH, or a combination thereof, and here, each R may be, independently, substituted or unsubstituted C3 to C40 (e.g., C5 or more and C24 or less) alkyl, substituted or unsubstituted C3 to C40 aliphatic hydrocarbon group such as substituted or unsubstituted alkenyl, substituted or unsubstituted C6 to C40 (e.g., C6 or more and C20 or less) aromatic hydrocarbon group such as substituted or unsubstituted C6 to C40 aryl group, or a combination thereof.

Examples of the organic ligands include: a thiol compound such as methane thiol, ethane thiol, propane thiol, butane thiol, pentane thiol, hexane thiol, octane thiol, dodecane thiol, hexadecane thiol, octadecane thiol, and benzyl thiol; amines such as methane amine, ethane amine, propane amine, butane amine, pentylamine, hexylamine, octylamine, nonyl amine, decyl amine, dodecyl amine, hexadecyl amine, octadecyl amine, dimethyl amine, diethyl amine, dipropyl amine, tributyl amine, and trioctyl amine; carboxylic acid compounds such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, and benzoic acid; phosphine compounds such as methyl phosphine, ethyl phosphine, propyl phosphine, butyl phosphine, pentyl phosphine, octyl phosphine, dioctyl phosphine, tributyl phosphine, and trioctyl phosphine; phosphine compounds or their oxide compounds such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, trioctyl phosphine oxide; diphenyl phosphine, triphenyl phosphine compounds, or their oxide compounds; C5 to C20 alkyl phosphinic acid and C5 to C20 alkyl phosphonic acids such as hexyl phosphinic acid, octyl phosphinic acid, dodecane phosphinic acid, tetradecane phosphinic acid, hexadecane phosphinic acid, and octadecane phosphinic acid; or the like, but is not limited thereto. The quantum dots may include the organic ligand alone or as a mixture of at least one kind. The hydrophobic organic ligand may not include a photopolymerizable moiety (e.g., an acrylate or methacrylate).

The transmission layer TL may be disposed in the third opening OP3. The transmission layer TL may be disposed in a portion corresponding to the blue-light emitting area BLA among the space partitioned by the bank BK. The transmission layer TL may transmit light incident from the light emitting element ED.

Although not shown in FIG. 5, the first color conversion layer CCL1, the second color conversion layer CCL2, and the transmission layer TL may each further include scatterers therein.

The display panel DP according to an embodiment may include an insulation pattern IL3 disposed on the first color conversion layer CCL1, the second color conversion layer CCL2, and the transmission layer TL. The insulation pattern IL3 may cover upper surfaces of the first color conversion layer CCL1, the second color conversion layer CCL2, and the transmission layer TL. A lower surface of the insulation pattern IL3 may be in contact with the upper surfaces of the first color conversion layer CCL1, the second color conversion layer CCL2, and the transmission layer TL. The insulation pattern IL3 may be disposed inside the first opening OP1, the second opening OP2, and the third opening OP3. An upper surface of the insulation pattern IL3 may be disposed lower than an upper surface of the bank BK.

Unlike what is shown in FIG. 5 to FIG. 7, the insulation pattern IL3 may cover an area corresponding to an entire area of a front surface of the display panel. For example, the insulation pattern IL3 may extend not only to an upper surface of the color conversion layers CCL1 and CCL2 and the transmission layer TL, but also to a partial area of a side surface of the bank BK, and above the upper surface of the bank. For example, the insulation pattern IL3 may also be disposed between the upper surface of the bank BK and the reflection layer RL. For example, the insulation pattern IL3 may cover a partial area of the side surface of the bank BK. For example, a partial area of the reflection layer RL disposed on the side surface of the bank BK may be disposed below the lower surface of the insulation pattern IL3. The insulation pattern IL3 may include an insulating material. For example, the insulation pattern IL3 may include an inorganic insulating material. For example, the insulation pattern IL3 may include at least one of silicon nitride (SiNₓ), silicon oxide (SiOₓ), and silicon oxynitride (SiOₓN_{y}). The insulation pattern IL3 may be formed by a deposition method such as a chemical vapor deposition method.

The insulation pattern IL3 may include a material having a refractive index value different from base materials included in the first color conversion layer CCL1, the second color conversion layer CCL2, and the transmission layer TL. For example, the insulation pattern IL3 may include a material having a refractive index value different from base materials included in the first color conversion layer CCL1, the second color conversion layer CCL2, and the transmission layer TL.

In some embodiments, a material having a refractive index lower than that of base materials included in the first color conversion layer CCL1, the second color conversion layer CCL2, and the transmission layer TL may be included. The refractive index deviation of base materials included in the color conversion layers CCL1 and CCL2 and the transmission layer TL and the insulation pattern IL3 may be greater than or equal to than about 0.1. For example, the refractive indices of base materials included in the first color conversion layer CCL1, the second color conversion layer CCL2, and the transmission layer TL may be about 1.59, and the refractive index of the insulation pattern IL3 may be about 1.38.

In case that the insulation pattern IL3 has a lower refractive index in comparison with a base material included in the color conversion layers CCL1 and CCL2, the probability of light being totally reflected at the interface of the color conversion layers CCL1 and CCL2 and the insulation pattern IL3 may increase. Accordingly, since the time for which light incident on the color conversion layers CCL1 and CCL2 and the transmission layer TL stays in the color conversion layers CCL1 and CCL2 and the transmission layer TL may be increased, the light conversion efficiency of the display device may be increased.

In another embodiment, the insulation pattern IL3 may include a material having a refractive index higher than that of the base materials included in the first color conversion layer CCL1, the second color conversion layer CCL2, and the transmission layer TL.

The reflection layer RL may be disposed on the bank BK. The reflection layer RL may also be partially disposed on the upper surface of the insulation pattern IL3. The reflection layer RL may include a first area RL1 and a second area RL2. Referring to FIG. 5 and FIG. 6A, the first area RL1 may be disposed on the side surface of the bank BK. The first area RL1 may cover the side surface of the bank BK. The first area RL1 may be in contact with side surfaces of the color conversion layers CCL1 and CCL2 and the insulation pattern IL3. The second area RL2 may cover the upper surface of the bank BK and an upper surface of the first area RL1. The second area RL2 may cover a partial area of the upper surface of the insulation pattern IL3. For example, the second area RL2 may cover the edge of the insulation pattern IL3. Referring to FIG. 6A, in an area simultaneously adjacent to a side surface and upper surface of the first area RL1, the second area RL2 may have an area protruding from the first area RL1. For example, the lower surface of the protruding area may be in contact with the partial area of the upper surface of the insulation pattern IL3.

The reflection layer RL may include a material capable of reflecting light. For example, the reflection layer RL may include a metallic material such as copper (Cu) and aluminum (Al). However, it is not limited thereto, and the reflection layer RL may include at least one or more of various materials capable of reflecting light. The first area RL1 and the second area RL2 may include the same material. For example, the first area RL1 and the second area RL2 may include the same metallic material. For example, a boundary may not be visible between the first area RL1 and the second area RL2. In another embodiment, the first area RL1 and the second area RL2 may include different materials. For example, the first area RL1 and the second area RL2 may include different metallic materials.

In an embodiment, light incident on the surface of the first area RL1 and the second area RL2 of the reflection layer RL may be reflected from the reflection layer RL and proceed into the color conversion layers CCL1 and CCL2 and the transmission layer TL. Accordingly, since the time for which light incident on the color conversion layers CCL1 and CCL2 and the transmission layer TL from the light emission layer EML stays in the color conversion layers CCL1 and CCL2 and the transmission layer TL may be increased, the light conversion efficiency of the display device may be increased.

Unlike FIG. 5 and FIG. 6A, the reflection layer RL may cover the entire upper surface of the insulation pattern IL3. For example, the reflection layer RL may include a material having high transmittance. For example, the reflection layer may include an insulating material. For example, the reflection layer RL may not include a metallic material. In case that the reflection layer RL covers the entire upper surface of the insulation pattern IL3, the reflection layer RL may include a material having a refractive index value of which a refractive index deviation with respect to the color conversion layers CCL1 and CCL2 and the transmission layer TL is greater than or equal to about 0.01.

The anti-reflection layer ARL may be disposed on the reflection layer RL. The anti-reflection layer ARL may cover an upper surface of the reflection layer RL. The anti-reflection layer ARL may cover an upper surface of the second area RL2 of the reflection layer RL. Referring to FIG. 6A, in an embodiment, widths of the anti-reflection layer ARL and the second area RL2 in the first direction DR1 may be substantially the same. As shown in FIG. 6A, a side surface of the anti-reflection layer ARL may be disposed on the same plane as a side surface of the second area RL2.

In another embodiment, a width of the anti-reflection layer ARL in the first direction DR1 may be greater than a width of the second area RL2 in the first direction DR1. For example, referring to FIG. 6B, the anti-reflection layer ARL may also be disposed on the side surface of the second area RL2 and a portion of the upper surface of the insulation pattern IL3. For example, the anti-reflection layer ARL may cover the side surface of the second area RL2 and the partial area of the upper surface of the insulation pattern IL3.

Referring to FIG. 7, a width w4 of the anti-reflection layer ARL in the horizontal direction may be greater than a maximum width w5 of the bank BK in the horizontal direction. Unlike what is shown in FIG. 7, the width w4 of the anti-reflection layer ARL in the horizontal direction may be substantially the same as the maximum width w5 of the bank BK in the horizontal direction. For example, the width w4 of the anti-reflection layer ARL in the horizontal direction may be greater than or equal to the maximum width w5 of the bank BK in the horizontal direction.

Referring to FIG. 7, the width w4 of the anti-reflection layer ARL in the horizontal direction may be smaller than a maximum width w6 of the pixel defining layer PDL in the horizontal direction. Unlike what is shown in FIG. 7, the width w4 of the anti-reflection layer ARL in the horizontal direction may be substantially the same as the maximum width w6 of the pixel defining layer PDL in the horizontal direction. For example, the width w4 of the anti-reflection layer ARL in the horizontal direction may be greater than or equal to the maximum width w6 of the pixel defining layer PDL in the horizontal direction.

In a plan view (see FIG. 8), the anti-reflection layer ARL may further extend from an inner side end portion of the bank BK toward the light emission layer EML. However, the anti-reflection layer ARL may not extend further above an upper surface of the light emission layer EML. For example, the anti-reflection layer ARL may be disposed to cover (or completely cover) the bank BK but not to overlap the light emission layer EML in the thickness direction (or third direction DR3). The anti-reflection layer ARL may overlap (or completely overlap) at least a partial area of the pixel defining layer PDL in the thickness direction (or third direction DR3). The pixel defining layer PDL may include an area that does not overlap the anti-reflection layer ARL in the thickness direction (or third direction DR3).

The first end of the anti-reflection layer ARL may be disposed between a first side end portion of the bank BK and a first side end portion of the pixel defining layer PDL.

The anti-reflection layer ARL may include an opaque material. The anti-reflection layer ARL may include a light blocking material. The anti-reflection layer ARL may include a material that is the same as at least one of color filter layers CF1, CF2, and CF3 described later. The anti-reflection layer ARL may include pigments and/or dyes of, for example, red, green, or blue color, and a photopolymer material. The anti-reflection layer ARL may include the same material as a third color filter layer CF3 described later. For example, the anti-reflection layer ARL may include an organic material or inorganic material including a blue pigment, and/or dye.

The anti-reflection layer ARL may cover the upper surface of the reflection layer RL, and accordingly, light entering an inside of the display panel DP from the outside of the display device may be absorbed by the anti-reflection layer ARL before reaching the surface of the reflection layer RL. Accordingly, the reflective ratio of light incident on the front surface from the outside may be decreased, thereby improving the visibility of the display device.

The display panel DP according to an embodiment may further include a filling layer FL disposed on the insulation pattern IL3 and the anti-reflection layer ARL, a second interlayer insulating layer IL4 disposed on the filling layer FL, the color filter layers CF1, CF2, and CF3 disposed on the second interlayer insulating layer IL4, and a second substrate SUB2 disposed on the color filter layers CF1, CF2, and CF3.

The filling layer FL may cover the upper surface and the side surface of the anti-reflection layer ARL and the upper surface of the insulation pattern IL3. The filling layer FL may cover at least a portion of the side surface of the second area RL2. The upper surface of the filling layer FL may be flat. The filling layer FL may include a transparent adhesive material. By means of the filling layer FL, components disposed on the first substrate SUB1 and components disposed on the second substrate SUB2 may be conjoined to each other.

The second interlayer insulating layer IL4 may be disposed on the filling layer FL. The second interlayer insulating layer IL4 may be disposed on the lower surfaces and side surfaces of the color filter layers CF1, CF2, and CF3. The second interlayer insulating layer IL4 may include an organic insulating material or an inorganic insulating material, and the inorganic insulating material may include at least one of silicon nitride (SiNₓ), silicon oxide (SiOₓ), and silicon oxynitride (SiOₓN_{y}).

The first color filter layer CF1, the second color filter layer CF2, and the third color filter layer CF3 may be disposed on the second interlayer insulating layer IL4.

The first color filter layer CF1 may overlap the first color conversion layer CCL1 in the thickness direction (or third direction DR3). The first color filter layer CF1 may transmit red light having passed through the first color conversion layer CCL1, and absorb light of other wavelengths, and a purity of red light emitted to the outside of the display device outer side may be increased.

The second color filter layer CF2 may overlap the second color conversion layer CCL2 in the thickness direction (or third direction DR3). The second color filter layer CF2 may transmit green light having passed through the second color conversion layer CCL2, and absorb light of other wavelengths, and a purity of green light emitted to the outside of the display device may be increased.

The third color filter layer CF3 may overlap the transmission layer TL in the thickness direction (or third direction DR3). The third color filter layer CF3 may transmit blue light having passed through the transmission layer TL, and absorb light of other wavelengths, and a purity of blue light emitted to the outside of the display device may be increased.

At least two or more among the first color filter layer CF1, the second color filter layer CF2, and the third color filter layer CF3 may overlap in the thickness direction (or third direction DR3) in the non-light emitting area NLA, to serve as a light blocking member. The non-light emitting area NLA may overlap the pixel defining layer PDL of the display unit DC and the bank BK of the color converter CC in the thickness direction (or third direction DR3).

The second substrate SUB2 may be disposed on the first color filter layer CF1, the second color filter layer CF2, and the third color filter layer CF3. The second substrate SUB2 may include a flexible material such as plastic that can be curved, bent, folded, or rolled.

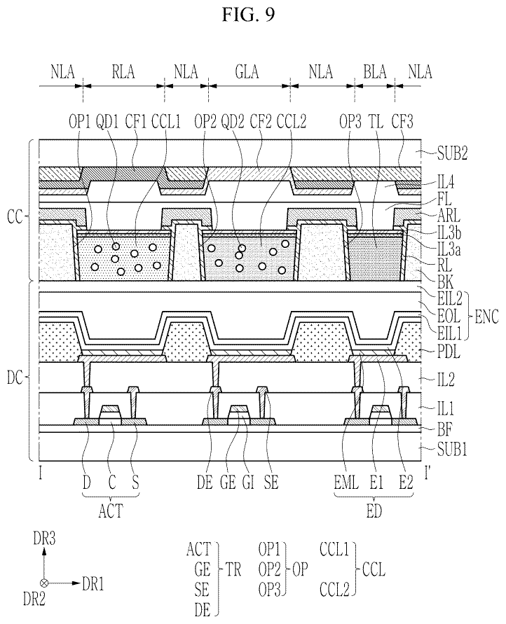

FIG. 9 is a schematic cross-sectional view of a display panel according to an embodiment. For example, FIG. 9 is a schematic cross-sectional view of the display panel DP taken along line I-I′ of FIG. 3.

The display panel shown in FIG. 9 has many parts that are the same as those in the previous embodiments, and hereinafter, the description will mainly focus on the differences from the previous embodiments. For example, the display panel shown in FIG. 9 may differ from the previous embodiments in some aspects in that multiple insulation patterns IL3a and IL3b disposed on the color conversion layers CCL1 and CCL2 and the transmission layer TL are included. The multiple insulation patterns IL3a and IL3b may have refractive indices different from each other. Referring to FIG. 9, although two insulation patterns IL3a and IL3b are illustrated, this is merely an example, and a display panel according to an embodiment may include three or more insulation patterns.

Referring to FIG. 9, in a display panel according to an embodiment, a lower insulation pattern IL3a may be disposed on the color conversion layers CCL1 and CCL2 and the transmission layer TL. An upper insulation pattern IL3b may be disposed on the lower insulation pattern IL3a. An upper surface of the lower insulation pattern IL3a may be in contact with a lower surface of the upper insulation pattern IL3b. An upper surface of the upper insulation pattern IL3b may be in contact with the filling layer FL.

In another embodiment, the lower insulation pattern IL3a and the upper insulation pattern IL3b may also be disposed on the upper surface of the bank BK. For example, unlike FIG. 5, the upper insulation pattern IL3b disposed on the lower insulation pattern IL3a and the lower insulation pattern IL3a may be disposed between the upper surface of the bank BK and a lower surface of the anti-reflection layer ARL. For example, the reflection layer RL may not be disposed on the upper surface of the bank BK and on the upper surface of the insulation pattern IL3.

The lower insulation pattern IL3a and the upper insulation pattern IL3b may each include at least one inorganic insulating material among silicon nitride (SiNₓ), silicon oxide (SiOₓ), and silicon oxynitride (SiOₓN_{y}). The lower insulation pattern IL3a and the upper insulation pattern IL3b may be formed by a deposition method such as a chemical vapor deposition method.

The lower insulation pattern IL3a and the upper insulation pattern IL3b may include a material having a refractive index lower than that of base materials included in the first color conversion layer CCL1, the second color conversion layer CCL2, and the transmission layer TL. The lower insulation pattern IL3a and the upper insulation pattern IL3b may include materials having refractive indices different from each other. For example, the upper insulation pattern IL3b may have a refractive index higher than the refractive index of the lower insulation pattern IL3a. The refractive index deviation of base materials included in the color conversion layers CCL1 and CCL2 and the transmission layer TL and the insulation patterns IL3a and IL3b may be greater than or equal to 0.1. For example, the refractive index of a base material included in the color conversion layers CCL1 and CCL2 and the transmission layer TL may be about 1.59, the refractive index of the lower insulation pattern IL3a may be about 1.36, and the refractive index of the upper insulation pattern IL3b may be about 1.38.

In another embodiment, the upper insulation pattern IL3b may include a material having a refractive index higher than that of base materials included in the first color conversion layer CCL1, the second color conversion layer CCL2, and the transmission layer TL. For example, the refractive index of a base material included in the color conversion layers CCL1 and CCL2 and the transmission layer TL may be about 1.59, the refractive index of the lower insulation pattern IL3a may be about 1.36, and the refractive index of the upper insulation pattern IL3b may be about 1.45.

The lower insulation pattern IL3a and the upper insulation pattern IL3b may include the same insulating material. For example, the refractive indices of the lower insulation pattern IL3a and the upper insulation pattern IL3b may be the same as or different from each other. In case that the lower insulation pattern IL3a and the upper insulation pattern IL3b include the same insulating material, a boundary between the lower insulation pattern IL3a and the upper insulation pattern IL3b may not be visible. The lower insulation pattern IL3a and the upper insulation pattern IL3b may include different insulating materials.

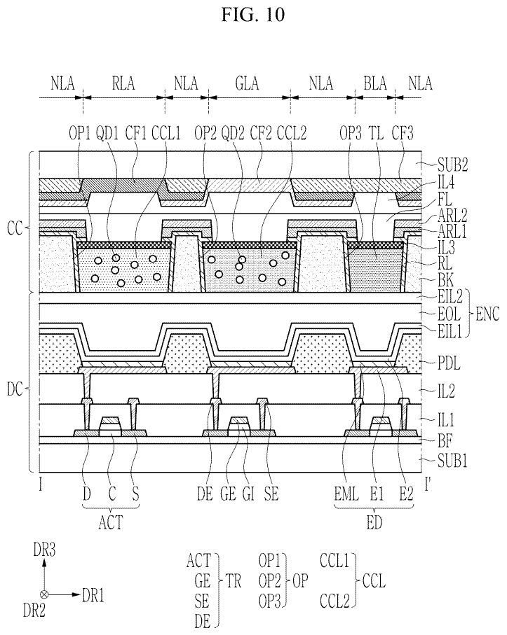

FIG. 10 is a schematic cross-sectional view of a display panel according to an embodiment. For example, FIG. 10 is a schematic cross-sectional view of the display panel DP taken along line I-I′ of FIG. 3.

The display panel shown in FIG. 10 has many parts that are the same as the previous embodiments, and hereinafter, the description will mainly focus on the differences from the previous embodiments. For example, the display panel shown in FIG. 10 may differ from the previous embodiments in some aspects in that the anti-reflection layer ARL includes multiple layers.

Referring to FIG. 10, in a display panel according to an embodiment, the anti-reflection layer ARL may include a first anti-reflection layer ARL1 and a second anti-reflection layer ARL2 disposed on the first anti-reflection layer ARL1. The first anti-reflection layer ARL1 and the second anti-reflection layer ARL2 may include light blocking materials. The first anti-reflection layer ARL1 and the second anti-reflection layer ARL2 may include different light blocking materials. For example, one of the first anti-reflection layer ARL1 and the second anti-reflection layer ARL2 may include a material that is the same as the color filter layers CF1, CF2, and CF3, and a second one may include a black matrix material. The black matrix may include a variety of materials known to block the transmission of light. For example, the black matrix may be formed by including at least one of an opaque organic material, a metallic material containing chromium, or carbon black.

In another embodiment, the anti-reflection layer ARL may have a structure in which two different color filter layers among three color filter layers CF1, CF2, and CF3 are stacked in the thickness direction (or third direction DR3).

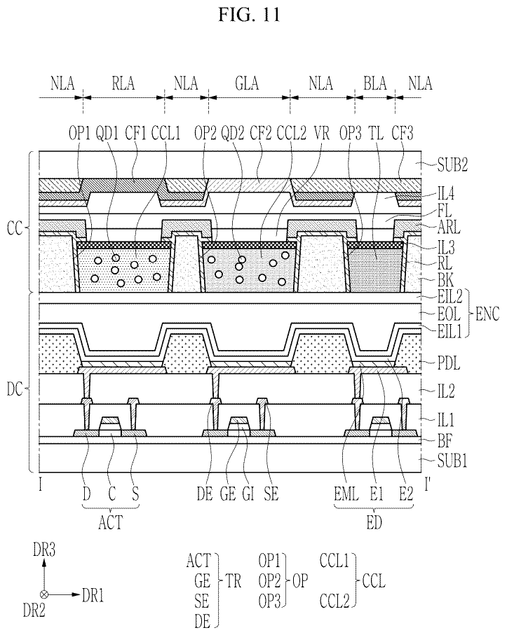

FIG. 11 is a schematic cross-sectional view of a display panel according to an embodiment. For example, FIG. 11 is a schematic cross-sectional view of the display panel DP taken along line I-I′ of FIG. 3.

The display panel shown in FIG. 11 has many parts that are the same as the previous embodiments, and hereinafter, the description will mainly focus on the differences from the previous embodiments. For example, the display panel shown in FIG. 11 may be different from the previous embodiments in some aspects in that a void area VR is included between the insulation pattern IL3 and the filling layer FL.

Referring to FIG. 11, a display panel according to an embodiment may include the void area VR disposed between the insulation pattern IL3 and the filling layer FL. In case that the display panel includes the void area VR, a lower surface of the filling layer FL overlapping the void area VR in the thickness direction (or third direction DR3) may be disposed between an upper surface and a lower surface of the anti-reflection layer ARL.

The void area VR may be an empty space. For example, the void area VR may be in a vacuum state. In another embodiment, air or at least one inert gas may be included in the void area VR. The inert gas may include, for example, nitrogen (N2) or Argon (Ar).

In case that the void area VR is in a vacuum state, or includes air or an inert gas, the refractive index of light in the void area VR may have the value of about 1.0.

The probability of light being totally reflected at the interface of the insulation pattern IL3 and the void area VR may increase, and accordingly, since the time for which light incident on the color conversion layers CCL1 and CCL2 and the transmission layer TL from the light emission layer EML stays in the color conversion layers CCL1 and CCL2 and the transmission layer TL may be increased, the light conversion efficiency of the display device may be increased.

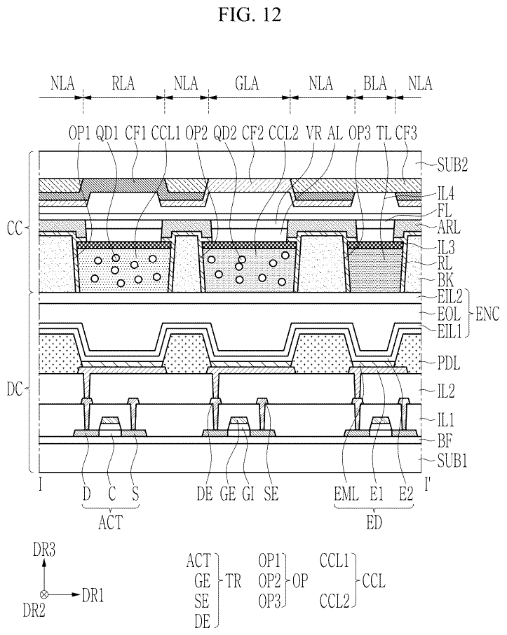

FIG. 12 is a schematic cross-sectional view of a display panel according to an embodiment. For example, FIG. 12 is a schematic cross-sectional view of the display panel DP taken along line I-I′ of FIG. 3.

The display panel shown in FIG. 12 has many parts that are the same as the previous embodiments, and hereinafter, the description will mainly focus on the differences from the previous embodiments. For example, the display panel shown in FIG. 12 may be different from the previous embodiments in some aspects in that a moisture absorbing layer AL and a void area VR disposed on the moisture absorbing layer AL disposed between the insulation pattern IL3 and the filling layer FL are included.

Referring to FIG. 12, the display panel DP according to an embodiment may further include the moisture absorbing layer AL disposed between the void area VR and the insulation pattern IL3, in comparison with the display panel described with reference to FIG. 11. The moisture absorbing layer AL may serve to prevent moisture from being introduced into the inside of the display device from the outside from the void area VR. The moisture absorbing layer AL may include an organic material such as polyacrylate resin, polyimide resin, or the like.

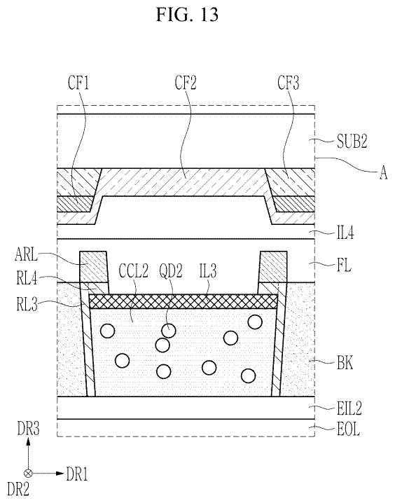

FIG. 13 is a schematic cross-sectional view of a display panel according to an embodiment. FIG. 13 is an enlarged schematic cross-sectional views representing the “A” area of FIG. 5.

The display panel shown in FIG. 13 has many parts that are the same as the previous embodiments, and hereinafter, the description will mainly focus on the differences from the previous embodiments.

Referring to FIG. 13, unlike the display panel described with reference to FIG. 5 to FIG. 7, in a display panel according to an embodiment, the anti-reflection layer ARL and the reflection layer RL may not be disposed on the upper surface of the bank BK. Referring to FIG. 13, the reflection layer RL may include a third area RL3 disposed on the side surface of the bank BK and a fourth area RL4 protruding outward in an upper portion of the third area RL3. The fourth area RL4 may be disposed on the upper surface of the insulation pattern IL3.

The anti-reflection layer ARL may be disposed on an upper surface of the third area RL3 and an upper surface of the fourth area RL4. The anti-reflection layer ARL may not be disposed on the upper surface of the bank BK.

A majority of light emitted from the light emission layer EML (see FIG. 5 and FIG. 7) may be incident on the inside of the color conversion layers CCL1 and CCL2 and the transmission layer TL, and may not be incident on the upper surface of the bank BK. Therefore, even if the reflection layer RL is not disposed on the upper surface of the bank BK, the time for which light incident on the color conversion layers CCL1 and CCL2 and the transmission layer TL from the light emission layer EML stays in the color conversion layers CCL1 and CCL2 and the transmission layer TL may be substantially the same as in the previous embodiments.

The color filter layers CF1, CF2, and CF3 may be stacked on the bank BK, and accordingly, light entering the inside of the display panel from the outside of the display device may be absorbed or blocked by the color filter layers CF1, CF2, and CF3 stacked in the thickness direction (or third direction DR3). Therefore, even if the anti-reflection layer ARL is not disposed on the upper surface of the bank BK, the level by which the external light reflection is decreased by the anti-reflection layer ARL may be substantially the same as in the previous embodiments.

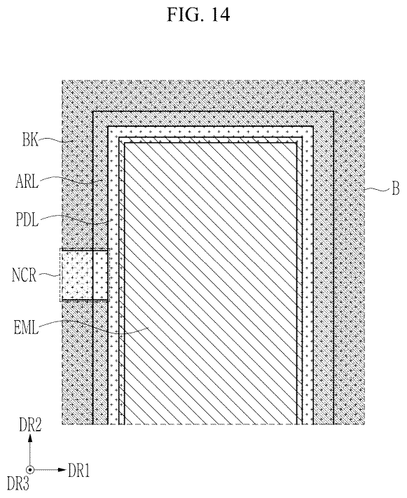

FIG. 14 is a schematic plan view of a display panel according to an embodiment.

The display panel shown in FIG. 14 has many parts that are the same as in the previous embodiments, and hereinafter, the description will mainly focus on the differences from the previous embodiments. A display device according to an embodiment may differ in some aspects from the previous embodiments in that it includes a non-continuous area NCR where the anti-reflection layer ARL is not disposed on a partial area of the bank BK.

Referring to FIG. 3 and FIG. 8, in the previous embodiments, in a plan view, the anti-reflection layer ARL may continuously extend along the edge of the light emission layer EML. In another embodiment, in the case of a display panel according to an embodiment, the non-continuous area NCR where the anti-reflection layer ARL is not disposed may be included, and accordingly, in a plan view, the anti-reflection layer ARL may not continuously extend along the edge of the light emission layer EML.

In FIG. 14, only one non-continuous area NCR is shown formed, but the display panel may include two or more non-continuous areas NCR.

In case that the display panel includes the non-continuous area NCR as shown in FIG. 14, external light reflection may increase, but at the same time, the aperture ratio of the display panel may increase so that the brightness of the display device may increase.

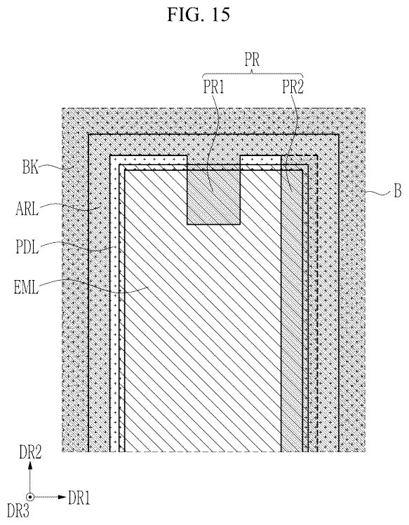

FIG. 15 is a schematic plan view of a display panel according to an embodiment.

The display panel shown in FIG. 15 has many parts that are the same as in the previous embodiments, and hereinafter, the description will mainly focus on the differences from the previous embodiments. A display device according to an embodiment may be different from the previous embodiments in some aspects in that it includes protrusion area PR which includes a first protrusion area PR1 and a second protrusion area PR2 extending in a direction from an inner surface of the anti-reflection layer ARL toward the light emission layer EML.

Referring to FIG. 15 in a plan view, the first and second protrusion areas PR1 and PR2 may extend in a direction from the inner surface of the anti-reflection layer ARL toward the light emission layer EML. The first and second protrusion areas PR1 and PR2 may be disposed on a portion of the upper surface of the light emission layer EML. For example, the first and second protrusion areas PR1 and PR2 may include an area overlapping a partial area of the light emission layer EML in the thickness direction (or third direction DR3).

The first and second protrusion areas PR1 and PR2 may be formed continuously with the anti-reflection layer ARL. Accordingly, the first and second protrusion areas PR1 and PR2 may include at least one surface that is in contact with the anti-reflection layer ARL. For example, as shown in FIG. 15, one surface of the first protrusion area PR1 may be in contact with a first side surface of the anti-reflection layer ARL, and two (or three) surfaces of the second protrusion area PR2 may be in contact with a second side surface of the anti-reflection layer ARL.

The first and second protrusion areas PR1 and PR2 may extend from a partial area of an inner surface of the anti-reflection layer ARL toward the light emission layer EML, like the first protrusion area PR1, or may extend from an entire area of the one inner surface of the anti-reflection layer ARL toward the light emission layer EML, like the second protrusion area PR2.

In case that the display panel includes the first and second protrusion areas PR1 and PR2 as shown in FIG. 15, the aperture ratio of the display device may decrease, but at the same time, the external light reflection may further decrease so that the visibility of the display device may be improved. A width of the protrusion area PR in the horizontal direction (e.g., the first and the second directions DR1 and DR2) may be set variously depending on the target reflective ratio.

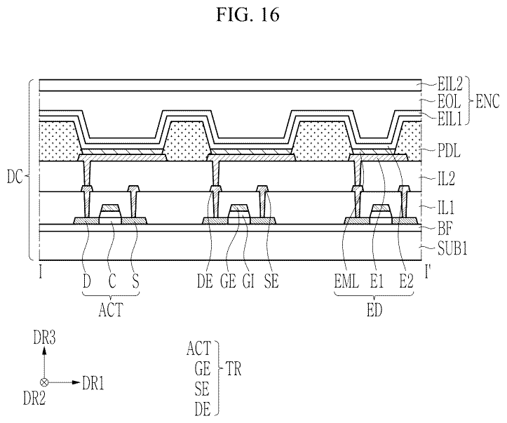

FIG. 16 to FIG. 22 are schematic process cross-sectional views for explaining a method of manufacturing a display panel according to an embodiment.

Firstly, as shown in FIG. 16, the transistor TR, the light emitting element ED disposed on the transistor TR and electrically connected to the transistor TR, and the encapsulation layer ENC covering the light emitting element ED may be formed on the first substrate SUB1. For example, an insulation layer such as the buffer layer BF, the first interlayer insulating layer IL1, the protective layer IL2, or the like may be formed between the first substrate SUB1 and the encapsulation layer ENC. The pixel defining layer PDL including the pixel opening may be formed on both sides of the light emitting element ED.

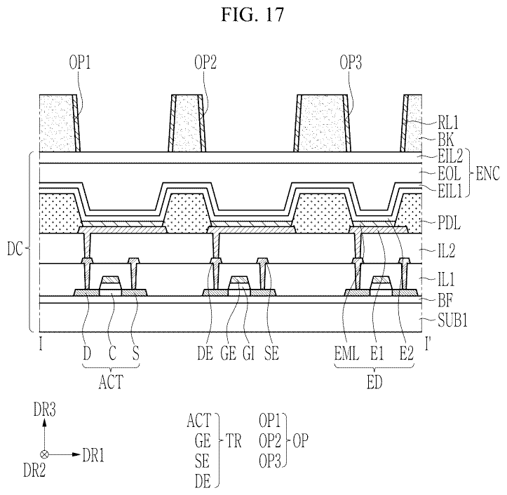

Subsequently, as shown in FIG. 17, the bank BK including multiple openings OP1, OP2, and OP3 may be formed on the encapsulation layer ENC. An insulating material, for example, an organic insulating material, may be deposited on the encapsulation layer ENC, and then patterned to form the bank BK. The size of multiple openings OP1, OP2, and OP3 of the bank BK may be different from or the same as each other. The width of the bank BK in the horizontal direction may gradually decrease away from the encapsulation layer ENC in the thickness direction (or third direction DR3).

Thereafter, the first area RL1 of the reflection layer RL may be formed on the bank BK. The first area RL1 may only be formed on the side surface of the bank BK. For example, a metal layer entirely covering the upper surface and side surface of the bank BK and bottom surfaces of multiple openings OP1, OP2, and OP3 may be formed and then patterned so that the first area RL1 covering the side surface of the bank BK is formed.

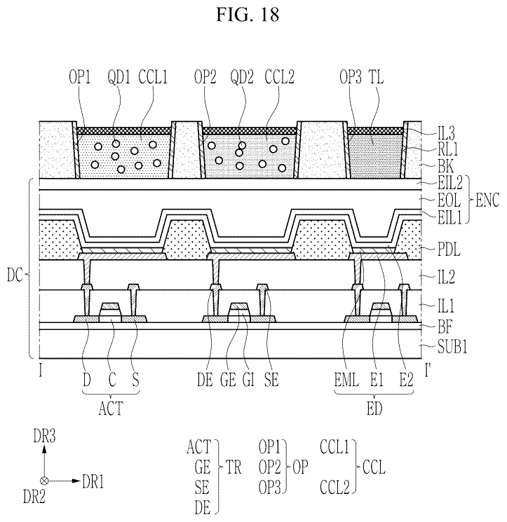

As shown in FIG. 18, the first color conversion layer CCL1, the second color conversion layer CCL2, and the transmission layer TL may be formed inside multiple openings OP1, OP2, and OP3, respectively. For example, the first color conversion layer CCL1 may be formed in the first opening OP1, the second color conversion layer CCL2 may be formed in the second opening OP2, and the transmission layer TL may be formed in the third opening OP3. The first color conversion layer CCL1 and the second color conversion layer CCL2 may include base materials and the quantum dots QD1 and QD2, respectively. The base material may include an organic material such as an epoxy-based resin, an acryl-based resin, a cardo-based resin or an imide-based resin. The first color conversion layer CCL1 may include the first quantum dots QD1. The first quantum dot QD1 may convert a third color light emitted from the light emission layer EML into a first color light. The first color light may be, for example, red light.

The second color conversion layer CCL2 may include the second quantum dot QD2. The second quantum dot QD2 may convert the third color light emitted from the light emission layer EML into a second color light. The second color light may be, for example, green light.

The transmission layer TL may transmit (or directly transmit) the third color light emitted from the light emission layer EML. The third color light may be, for example, blue light.

Thereafter, the insulation pattern IL3 covering the upper surfaces of the first color conversion layer CCL1, the second color conversion layer CCL2, and the transmission layer TL may be formed. The insulation pattern IL3 may be an inorganic insulation layer formed by a chemical vapor deposition method.

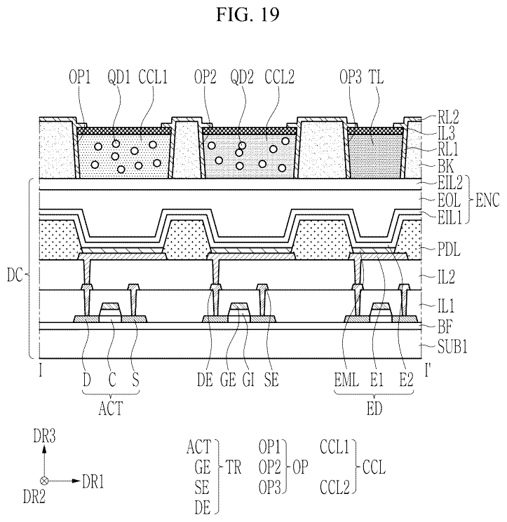

As shown in FIG. 19, the second area RL2 of the reflection layer RL may be formed on the upper surface of the bank BK. The second area RL2 may cover the upper surface of the bank BK, a portion of the upper surface of the first area RL1 and a side surface of the first area RL1. The second area RL2 may also cover a partial area of the upper surface of the insulation pattern IL3. The second area RL2 may include a light reflection material. For example, the second area RL2 may include a metallic material. The second area RL2 may include a material that is the same as the first area RL1. However, it is not limited thereto, and the second area RL2 may include a material that is the same as the first area RL1.

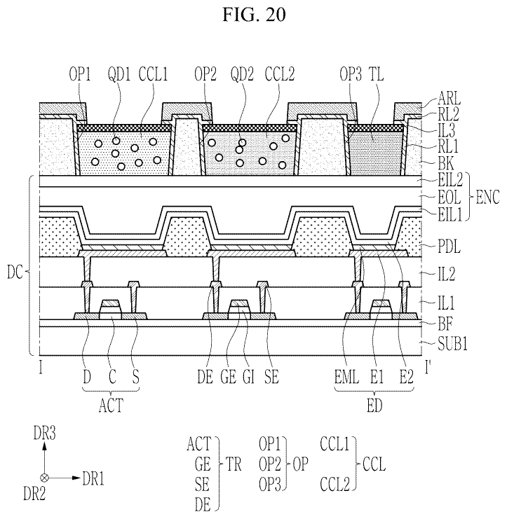

As shown in FIG. 20, the anti-reflection layer ARL may be formed on the upper surface of the second area RL2. The anti-reflection layer ARL may cover (or completely cover) the upper surface of the second area RL2. In another embodiment, the width of the anti-reflection layer ARL in the horizontal direction may be greater than a width of the second area RL2 in the horizontal direction. For example, the anti-reflection layer ARL may cover the side surface of the second area RL2 and a partial area of the upper surface of the insulation pattern IL3.

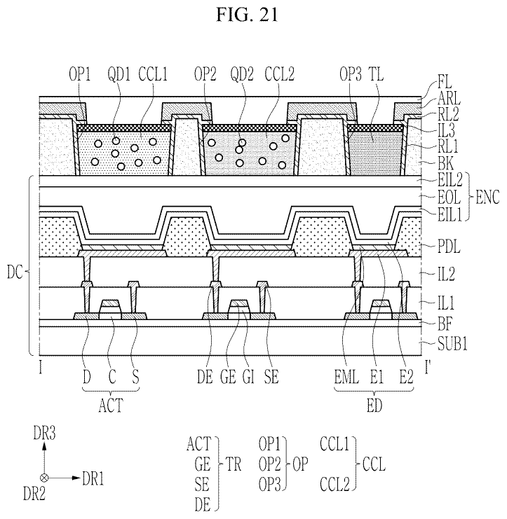

As shown in FIG. 21, the filling layer FL may be formed covering the upper surface and the side surface of the anti-reflection layer ARL and the upper surface of the insulation pattern IL3. The filling layer FL may include a transparent adhesive material.

Subsequently, multiple color filter layers CF1, CF2, and CF3 may be formed on the second substrate SUB2, and the second interlayer insulating layer IL4 may be formed on multiple color filter layers CF1, CF2, and CF3. The second interlayer insulating layer IL4 may include an organic insulating material or an inorganic insulating material, and the inorganic insulating material may include at least one of silicon nitride, silicon oxide, and silicon oxynitride.

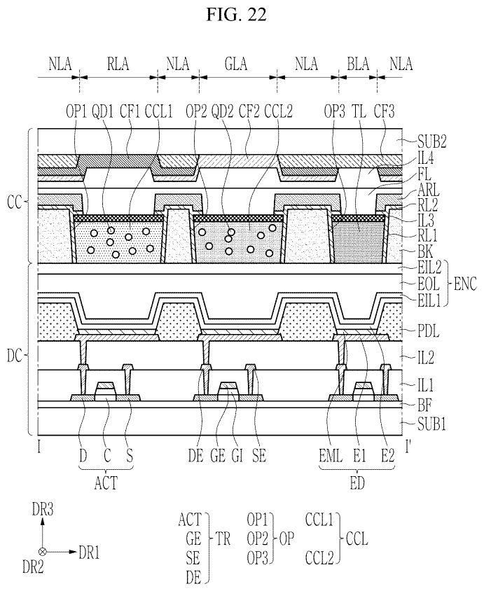

As shown in FIG. 22, the second substrate SUB2 in which multiple color filter layers CF1, CF2, and CF3 and second interlayer insulating layer IL4 are formed may be rotated and disposed on the first substrate SUB1. For example, the filling layer FL and the second interlayer insulating layer IL4 are placed to face each other and then attached to the second substrate SUB2 and the first substrate SUB1 so that the display panel described with reference to FIG. 5 may be manufactured.

A display device according to an embodiment may be applied to various electronic devices. An electronic device according to an embodiment may include the display device, and may further include modules or devices having additional functions other than the display device.

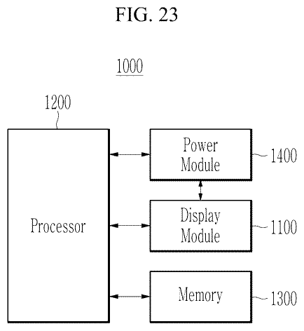

FIG. 23 is a schematic block diagram of an electronic device according to an embodiment. Referring to FIG. 23, the electronic device 1000 according to an embodiment may include a display module 1100, a processor 1200, a memory 1300, and a power module 1400.

The processor 1200 may include at least one of a central processing unit (CPU), an application processor (AP), a graphic processing unit (GPU), a communication processor (CP), an image signal processor (ISP), and a controller.

The memory 1300 may store data information necessary for operations of the processor 1200 or the display module 1100. In case that the processor 1200 executes an application stored in the memory 1300, video data signals and/or input control signals are transmitted to the display module 1100, and the display module 1100 can process the received signals to output video information through the display screen.

The power module 1400 may include a power supply module such as a power adapter or battery device, and a power conversion module that converts the power supplied by the power supply module to generate the power necessary for the operation of the electronic device 1000.

At least one of components of the electronic device 1000 may be included in the display device according to the above-described embodiments. Additionally, some of the individual modules that are functionally included in a single module may be incorporated into the display device, while others may be provided separately from the display device. For example, the display device may include the display module 1100, while the processor 1200, memory 1300, and power module 1400 may be provided in a form of other devices in the electronic device 1000 that are not part of the display device.

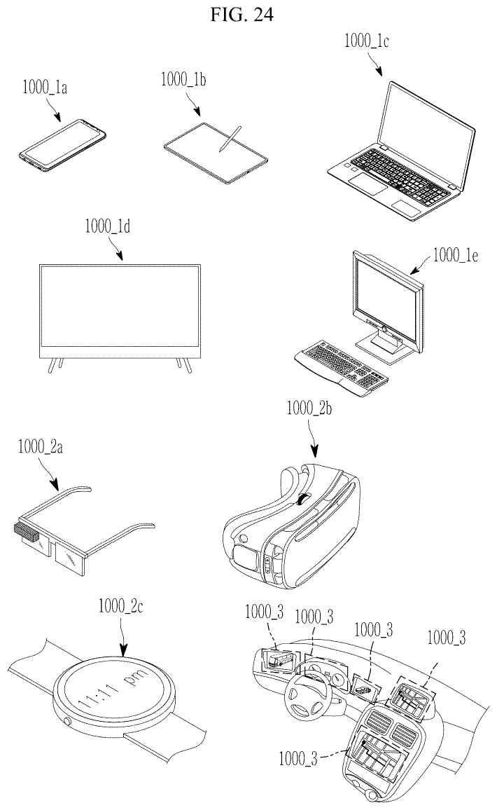

FIG. 24 shows schematic diagrams of electronic devices according to various embodiments.

Referring to FIG. 24, various electronic devices with the display device according to the embodiments may include not only image display electronic devices such as smartphones 1000_1a, tablet PCs 1000_1b, laptops 1000_1c, TVs 1000_1d, desktop monitors 1000_1e, but also wearable electronic devices with display modules such as smart glasses 1000_2a, head-mounted displays 1000_2b, smart watches 1000_2c, as well as automotive electronic devices with display modules 1000_3 such as those placed on car dashboards, center fascias, CID (Center Information Display), room mirror displays, and so on.

While this disclosure has been described in connection with what is presently considered to be practical embodiments, it is to be understood that the disclosure is not limited to the disclosed embodiments, but, on the contrary, is intended to cover various modifications and equivalent arrangements included in the spirit and scope of the appended claims.

What is claimed is:

1. A display device, comprising:
a substrate;
a transistor disposed on the substrate;
a light emitting element including a light emission layer disposed on the transistor, and electrically connected to the transistor;
a bank disposed on the light emitting element, and including an opening;
a color conversion layer disposed in the opening, and including a quantum dot;
a reflection layer disposed on an upper surface and a side surface of the bank; and
an anti-reflection layer covering at least a portion of an upper surface and a side surface of the reflection layer.

2. The display device of claim 1, wherein the reflection layer includes a first area covering a side surface of the bank and a second area covering the upper surface of the bank and an edge portion of the color conversion layer on the first area.

3. The display device of claim 2, further comprising:
an insulation pattern disposed on the color conversion layer,
wherein the second area covers at least a portion of the upper surface of the insulation pattern.

4. The display device of claim 3, wherein the insulation pattern has a different refractive index value from a refractive index of the color conversion layer, and the insulation pattern includes a plurality of layers having refractive indices different from each other.

5. The display device of claim 3, further comprising:
a filling layer disposed on the anti-reflection layer and the insulation pattern,
wherein an upper surface of the anti-reflection layer is in contact with the filling layer, and a lower surface of the anti-reflection layer is in contact with the reflection layer.

6. The display device of claim 5, wherein a void area is disposed between the filling layer and the insulation pattern.

7. The display device of claim 6, wherein the void area is in a vacuum state.

8. The display device of claim 6, wherein the void area includes air or an inert gas.

9. The display device of claim 6, further comprising:
a moisture absorbing layer disposed on the insulation pattern,
wherein the void area is disposed between the moisture absorbing layer and the filling layer.

10. The display device of claim 1, further comprising:
color filter layers disposed on the color conversion layer, wherein
the anti-reflection layer and at least one of the color filter layers includes a same material,
the color filter layers include a first color filter layer that transmits red light, a second color filter layer that transmits green light, and a third color filter layer that transmits blue light, and
the anti-reflection layer and the third color filter layer includes a same material.

11. The display device of claim 1, wherein
the anti-reflection layer further includes a first anti-reflection layer disposed on the reflection layer and a second anti-reflection layer disposed on the first anti-reflection layer,
the first anti-reflection layer and the second anti-reflection layer comprise different materials, and
the reflection layer includes a metallic material.

12. The display device of claim 1, further comprising:
a pixel defining layer disposed on sides of the light emission layer,
wherein a width of the anti-reflection layer in a horizontal direction is greater than or equal to a width of the bank in the horizontal direction, and smaller than or equal to a width of the pixel defining layer in the horizontal direction.

13. A display device, comprising:
a substrate;
a transistor disposed on the substrate;
a light emitting element including a light emission layer disposed on the transistor, and electrically connected to the transistor;
a bank disposed on the light emitting element, and including an opening;
a color conversion layer disposed in the opening of the bank, and including a quantum dot; and
a reflection layer disposed on a side surface of the bank,
wherein the reflection layer includes:
a first area covering the side surface of the bank; and
a second area covering an edge portion of the color conversion layer on the first area.

14. The display device of claim 13, further comprising:
an anti-reflection layer covering at least a portion of an upper surface and a side surface of the reflection layer; and
an insulation pattern disposed on the color conversion layer,
wherein the second area covers at least a portion of a pattern upper surface.

15. The display device of claim 14, wherein the insulation pattern has a different refractive index value from a refractive index of the color conversion layer.

16. The display device of claim 13, further comprising:
a pixel defining layer disposed on sides of the light emission layer,
wherein a width of an anti-reflection layer in a horizontal direction is greater than or equal to a width of the bank in the horizontal direction, and smaller than or equal to a width of the pixel defining layer in the horizontal direction.

17. An electronic device comprising:
a display device including:
a substrate;
a transistor disposed on the substrate;
a light emitting element including a light emission layer disposed on the transistor, and electrically connected to the transistor;
a bank disposed on the light emitting element, and including an opening;
a color conversion layer disposed in the opening of the bank, and including a quantum dot;
a reflection layer disposed on an upper surface and a side surface of the bank; and
an anti-reflection layer covering at least a portion of an upper surface and a side surface of the reflection layer.

18. The electronic device of claim 17, wherein the reflection layer includes a first area covering a side surface of the bank and a second area covering the upper surface of the bank and an edge portion of the color conversion layer on the first area.

19. An electronic device, comprising:
a display device including:
a substrate;
a transistor disposed on the substrate;
a light emitting element including a light emission layer disposed on the transistor, and electrically connected to the transistor;
a bank disposed on the light emitting element, and including an opening;
a color conversion layer disposed in the opening of the bank, and including a quantum dot; and
a reflection layer disposed on a side surface of the bank,
wherein the reflection layer includes:
a first area covering the side surface of the bank; and
a second area covering an edge portion of the color conversion layer on the first area.

20. The electronic device of claim 19, further comprising:
an anti-reflection layer covering at least a portion of an upper surface and a side surface of the reflection layer.
